(19) United States
(12) Patent Application Publication
(10) Pub. No.: US 2016/0344300 A1
(43) Pub. Date: Nov. 24, 2016

(54) Synergistic Applications of Multi-ON-Mode Bidirectional Bipolar Switch

(71) Applicant: Ideal Power Inc., Austin, TX (US)

(72) Inventor: William C. Alexander, Spicewood, TX (US)

(73) Assignee: Ideal Power Inc., Austin, TX (US)

(21) Appl. No.: 15/158,553

(22) Filed: May 18, 2016

Related U.S. Application Data
(60) Provisional application No. 62/162,907, filed on May 18, 2015.
(60) Provisional application No. 62/162,912, filed on May 18, 2015.
(60) Provisional application No. 62/163,720, filed on May 19, 2015.
(60) Provisional application No. 62/163,780, filed on May 19, 2015.
(60) Provisional application No. 62/163,818, filed on May 19, 2015.
(60) Provisional application No. 62/163,827, filed on May 19, 2015.
(60) Provisional application No. 62/163,833, filed on May 19, 2015.

(51) Int. Cl. H02M 5/293; H03K 17/66; H03K 17/68

(52) U.S. Cl. CPC H02M 5/293; H03K 17/68; H03K 17/666

(57) ABSTRACT

The present application teaches configurations in which the multiple-ON-mode bidirectional bipolar switch is used to provide very simple circuit configurations which can—when requirements are not stringent—perform certain electrical conversions which might otherwise require a PPSA (Power Packet Switching Architecture) converter.

### CROSS-REFERENCE

Priority is claimed from U.S. provisional patent applications 62/162,907, 62/162,912, 62/163,720, 62/163,780, 62/163,818, 62/163,827, and 62/163,833, each and every one of which is hereby incorporated by reference, both singly and in combination.

### BACKGROUND

The present application relates to power circuit configurations, and particularly to power converter circuits.

Note that the points discussed below may reflect the hindsight gained from the disclosed inventions, and are not necessarily admitted to be prior art.

The “B-TRAN” (Bi-directional Bi-polar Junction Transistor) is a different kind of device, which was first disclosed in published U.S. application US 2014-0375287. This application disclosed a fully bidirectional bipolar transistor, having emitter/collector regions on both faces of a semiconductor die, and also having base contact regions on both faces. In one group of embodiments (shown e.g. in FIG. 13A of that application, and described in paragraph [0083]), the emitter/collector regions are laterally separated from the base contact regions by a dielectric-filled trench. This reduces same-side carrier recombination in the ON state.

Application US 2014-0375287 also describes some surprising aspects of operation of the device, particularly in having multiple on-state phases of operation. Notably: 1) when the device is turned on, it is preferably first operated merely as a diode, and base drive is then applied to reduce the on-state voltage drop. 2) Base drive is preferably applied to the base nearest whichever emitter/collector region will be acting as the collector (as determined by the external voltage seen at the device terminals). 3) A two-stage turnoff sequence is preferably used. 4) In the off state, base-emitter voltage (on each side) is limited by a low-voltage diode which parallels that base-emitter junction.

A somewhat similar structure was shown and described in application WO2014/122472 of Wood. However, that application is primarily directed to different structures. The Wood application also does not describe the methods of operation described in the US 2014-0375287 application. The Wood application also does not appear to describe lateral trench isolation between emitter/collector regions and base contact regions.

The present application provides improvements in structures of this type, in methods of operating such structures, and in systems which incorporate such structures.

A B-TRAN is in the “active off-state” when the e-base (base on emitter side) is shorted to the emitter, and the c-base (base on the collector side) is open. In this state with an NPN B-TRAN, the collector is the anode (high voltage side), and the emitter is the cathode (low voltage side).

The B-TRAN is also off when both bases are open, but due to the high gain of the B-TRAN in this state, the breakdown voltage is low. The series combination of a normally-ON JFET and a Schottky diode attached between each base on its respective emitter/collector, as previously disclosed, will significantly increase the blocking voltage in this “passive off-state”. The JFETs are turned off during normal operation.

The e-base is essentially at a constant voltage—it varies only about 0.1 V from a low drive to a high drive condition. The c-base, in contrast, is a nearly constant current drive, even as the voltage is varied from 0 V above the collector to about 0.6V. Instead of the c-base current changing with c-base voltage, V_{ce} changes. At c-base of 0V (c-base shorted to collector), there is a certain gain that depends on the emitter current density, and V_{ce} is nominally 0.9 V over a large range of current density. Raising c-base to 0.1 V above the collector does not change the gain, but it lowers Vice by nominally 0.1 V. Raising the c-base to 0.6V drops V_{ce} to about 0.2 or 0.3 V.

This device has a three-layer structure (PNP or NPN), but has a control switch on each side. This double-sided switch arrangement enables a kind of hybrid operation, where the device can behave as a MOSFET while turning off, and can operate as a fully bipolar transistor, with low voltage drop, when fully on. The B-TRAN also has identical behavior in each direction, enabling it to block voltage or conduct current in each direction with equal performance.

As an NPN IGBT (or diode), it is turned on by closing the switch on the higher voltage (collector) side while leaving the switch on the lower voltage (emitter) side open (Diode On mode, FIG. 2A). In the on state (Transistor On mode, FIG. 2B), B-TRAN operation may be seen to be identical to conventional (one-sided) IGBT on-state operation, but instead of turning off by simply opening the top switch, with the commensurate slow turn-off, the B-TRAN is turned off by first closing the bottom switch, which removes the forward bias on the lower P−/N+ diode, and restricts its ability to inject charge carriers into the P region (Pre-Turn-Off mode, FIG. 2C). Also, charge carriers are actively removed from the P− region as a result of current flow via the bottom switch. The result is a rapid and large reduction in the conductivity of the P− region just prior to final turn-off, which is produced by finally opening the top switch (Off mode, FIG. 2D). In this off configuration, the device may be seen to be configured as a MOSFET rather than an IGBT, which results in fast turn-off and near-zero tail current (FIG. 5).

Note that only one of the four phases shown is strictly an OFF state, and that a “diode turn-on” state and a “pre-turnoff” state separate the low voltage drop state from the fully OFF state.

The figures below show performance simulation results, run in Silvaco Atlas, for 650 V and 1200 V B-TRANs at 25° C. The 1200V device has a gain of 14 at 67 A/cm² and V_{ce} of 0.2 V, and the 650 V device has a gain of 24 at 100 A/cm² and V_{ce} of 0.2V.

FIG. 3 shows the voltage across the 1200 V B-TRAN (Vce) as well as emitter current (Iₑₘᵢₜₜₑᵣ) and collector-base current (I_{cb}) during three modes of operation—diode-on, transistor-on, and pre-turn-off. From 0 to 2 uS, the device is in diode-on mode (e-base is open), which is shown in more detail in FIG. 4. Total turn-on energy is only 0.34 mJ, and is calculated as the total power dissipated by the device from 0 to 2 uS. After 2 uS, Icb has fallen sufficiently for the controls to disconnect c-base from the collector, and attach it to a 7 A, 0.6 V power supply, which then lowers Vice from about 1 V to 0.2 V. Thus, an input power of 4.2 watts produces a power savings of 100×0.8V, or 80 W. Gain is 14.

At 7 microseconds, the device enters pre-turn-off mode, where the c-base is disconnected from the power supply and reconnected to the collector, and e-base is shorted to the emitter. This produces a rapid reduction in charge carriers from the P− (base, or “drift”) region. At 8 uS, the connection to the c-base is opened, producing the turn-off waveform of FIG. 5. Voltage rise time is about 110 nS, followed by a current fall time of less than 20 nS, which is very similar to a MOSFET turn-off current, resulting in a total turn-off energy of only 2.6 mJ in this example.

By comparison, FIG. 6 shows a typical turn-off waveform for an IGBT, showing the tail current that causes the IGBT to have much higher turn-off losses as compared with the B-TRAN.

FIG. 10 is a detailed sectional view of one example of a B-TRAN device structure.

A new kind of power converter was disclosed in U.S. Pat. No. 7,599,196 entitled “Universal power conversion methods,” which is incorporated by reference into the present application in its entirety. FIG. 11 shows one such exemplary converter. This patent describes a bidirectional (or multidirectional) power converter which pumps power into and out of a link inductor which is shunted by a capacitor.

The switch arrays at the ports are operated to achieve zero-voltage switching by totally isolating the link inductor+capacitor combination at times when its voltage is desired to be changed. (When the inductor+capacitor combination is isolated at such times, the inductor's current will change the voltage of the capacitor, as in a resonant circuit. This can even change the sign of the voltage, without loss of energy.) This architecture is now referred to as a “current-modulating” or “Power Packet Switching” architecture (PPSA). Bidirectional power switches are used to provide a full bipolar (reversible) connection from each of multiple lines, at each port, to the rails, i.e. the internal lines across which the link inductor and its capacitor are connected.

### Synergistic Applications of Multi-ON-Mode Bidirectional Bipolar Switch

The present application teaches configurations in which the multiple-ON-mode bidirectional bipolar switch is used to provide very simple circuit configurations which can—when requirements are not stringent—perform certain electrical conversions which might otherwise require a PPSA (Power Packet Switching Architecture) converter. Magnetic power-handling elements, such as transformers or chokes, are not normally required. Preferably the switch is a symmetrically-bidirectional solid-state switch with bipolar conduction. One example of a suitable switch for use in the claimed inventions is a B-TRAN switch, described e.g. in published PCT application WO2014/210072; another example is an M-TRAN switch, described e.g. in copending application WO2016/064923. The most attractive applications are those where only step-down voltage conversion is required, without step-up, phase change, frequency change, or other advanced functions which can be performed by a PPSA converter. When such more advanced functions are not required, the disclosed innovations provide some extremely simple configurations which can meet relaxed application requirements.

One disclosed example of such a synergistic application is an AC voltage regulator. This is implemented, in disclosed embodiments, as a simple buck converter, replicated for each of the n hot lines of each power port. The input and output ports have equal numbers of lines, and the use of AC switches means that the voltage regulation or conversion operation proceeds identically regardless of what the instantaneous polarity of any one of the AC power connections is—as long as the power transfer is to reduced voltage magnitude only.

Another disclosed example of such a synergistic application is a Matrix converter. Note that this provides a SIMPLE way to solve a simple problem without the expense of a PPSA.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1 shows a first example of use of a bidirectional bipolar-conduction switch using multiple ON states. This example is a matrix switch used to provide VFD directly from the line with high efficiency.

FIGS. 2A-2D show an example of the phases of operation of a B-TRAN device. Note that only one of the four phases shown is strictly an OFF state, and that a “diode turn-on” state and a “pre-turnoff” state separate the low voltage drop state from the fully OFF state.

FIG. 3 shows simulated voltage and current for three modes of operation of a sample B-TRAN.

FIG. 4 shows simulated voltage and current for diode turn-on for a sample B-TRAN.

FIG. 5 shows simulated voltage and current for pre-turn-off for a sample B-TRAN.

FIG. 6 shows the slow turn-off of a conventional IGBT.

FIG. 7 shows the use of bidirectional bipolar-conduction switches using multiple ON states for operation of an electric vehicle (EV) or hybrid vehicle (HV).

FIG. 8 shows the use of a bidirectional bipolar-conduction switch using multiple ON states as an AC switch for AC power control.

FIG. 9 is a simple buck converter, which is easily implemented with B-TRANs,

FIG. 10 is a detailed sectional view of one example of a B-TRAN device structure.

FIG. 11 shows an example of the use of a bidirectional bipolar-conduction switch using multiple ON states for the phase legs of a Power Packet Switching Architecture (PPSA) power converter. Notice that, in a two-port converter with three-phase AC on either side, 12 bidirectional switches are required.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

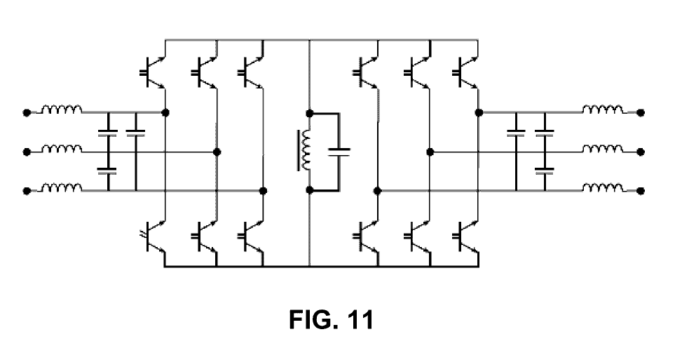

The B-TRAN is most advantageous in topologies that take full advantage of an AC switch, such as Ideal Power's PPSA (FIG. 11) or the EV drive topology shown below (FIG. 7). In such topologies, reverse recovery does not occur, and converter performance can be predicted from forward voltage drop and switching losses. Thus it is instructive to compare with other device types using these parameters. To form an AC switch with IGBTs, 2 IGBTs and 2 diodes are used. To form an AC switch with a MOSFET, two MOSFETs are used back-to-back (anti-series).

Although these switches will likely be operating at higher temperatures, comparisons were done at 25 C as that was the only temperature common to all data sheets. Performance of all switches degrades with higher temperature, but the B-TRAN will degrade less since it has such low losses, and therefore will operate at lower temperatures as compared with other devices.

Estimated B-TRAN total loss is about ⅛th of the IGBT/Diode loss, due both to the much lower B-TRAN conduction loss, and much lower B-TRAN switching loss.

The B-TRAN, as a switch topology, can be implemented in other materials besides silicon, such as silicon carbide.

Another competing technology is III-N devices, e.g. GaN MOSFETs. GaN MOSFETs are available in small packages up to 450 V (see data sheets for EPC2025 and EPC2027 on Digikey.com). These two devices each have a die size of 1.95 by 1.95 mm (0.038 cm̂2), with the 300 V device having a 150 m-ohm resistance and the 450 V device having a 400 in-ohm resistance at 25 C, indicating that on-resistance with these devices increases by more than the square of the voltage. In an AC configuration, the 450 V GaN device has 800 in-ohm resistance, so to match the 650 V B-TRAN voltage drop of 0.2 V at 150 A on a 1.5 cm̂2 die, 1200 of the 450 V GaN devices are needed. At $5 each, this would come to $6,000 worth of GaN to match the B-TRAN in on resistance, but still would not match the B-TRAN in voltage capability (450 V GaN vs 650 V B-TRAN).

Comparison with AC and DC Switch Configurations for EV Drive:

650 V is a common voltage for IGBT/diode modules used in EV drives. These are typically large modules that conduct high current, and are DC (i.e. these modules block voltage in only one direction). Such a module from Bosch is summarized below (MH6560C), and compared with an equivalent capacity 650 V B-TRAN. From simulations, the 650 V B-TRAN has a high gain of 23 at 150 A on a 1.5 cm̂2 die (100 A/cm̂2), and for this comparison, 4 such die are assumed (6 cm̂2 die area) to support 600 A. Two topologies are possible for this application—the AC link of FIG. 7, as discussed above, which eliminates reverse recovery related losses, or the conventional DC link. The AC link requires AC switches, such as the B-TRAN, or anti-series pairs of IGBT/diode modules. The following analysis discusses both versions.

Again, the B-TRAN, as simulated, is predicted to have significantly better performance as compared with its competition, with about one tenth of the total losses of the IGBT/diode module in the AC link converter. As a native AC switch, the B-TRAN is seen to perform much better in the AC link topology, with less than ½ the loss of the DC link topology, but even in the DC link topology the B-TRAN has only about ⅓ the loss of the IGBT/diode module. (Power calculations include 15 W of base drive power for each active phase leg.)

The B-TRAN in the AC switch topology has another, previously unstated advantage—no significant voltage overshoot from reverse recovery transients. This will allow the AC link B-TRAN converter to operate with at least 50% higher DC bus voltage, thereby increasing the power rating of the converter by 50%, which decreases the relative costs of the B-TRANs.

The B-TRAN differs substantially from conventional Bipolar Junction Transistors (BJTs). The B-TRAN and BJT have in common a three-layer structure (NPN or PNP), and the ability to conduct current with voltage drops much less than 0.7 volts. However, these two technologies are constructed and operated very differently. The BJT has been used for over 50 years, preceding both MOSFETs and IGBTs. While the B-TRAN (like the IGBT) has thin surface layers for emitter and collector and a wide, central base layer, the BJT has a wide collector, thin emitter and thin base in between, with only a single base connection. Thus, the BJT has no collector-side base connection as does the B-TRAN and IGBT. This results in comparatively poor performance in gain vs current density, switching performance and the inability to be used as a diode.

Since the conventional bipolar transistor is asymmetric, it cannot be used as an AC switch. As can be seen on the data sheet of a typical high voltage BJT (MJW18020 with 450 Vceo), the current density at a gain of 10 is only about 10 A/cm̂2 ( 1/10th of the 650 V B-TRAN), and switching times are very long: storage times are in the range of microseconds, and rise and fall times on the order of hundreds of nanoseconds.

### Applications of the B-TRAN

Just a few of the many possible applications of the B-TRAN are shown below. As these examples illustrate, the B-TRAN topology is a simple, yet radically different topology for power semiconductors. It combines the fast, low loss switching of a MOSFET, the high current density of the IGBT, the low forward voltage drop of the BJT, and a unique bi-directionality, which allows its use in highly advantageous AC link converter topologies. B-TRANs offer the potential to improve efficiency and system economics of a wide variety of power converter applications including variable frequency (VFD) motor drives, electrified vehicle traction drives, PV inverters and wind converters.

### Three Phase AC Power Control

SCRs are widely used for controlling AC power, but have a significant power loss due to their approximately 1.4 V drop—600% higher than the 0.2 V drop of the B-TRAN. Contactors too are used widely for such applications, and have much lower losses than SCRs, but suffer from a limited life span and environmental degradation. A B-TRAN contactor replacement will also have much lower losses than SCRs, but with an unlimited life and little to no environmental degradation. Both SCRs and contactors cannot control intra-cycle fault currents, which often leads to blown fuses and unsafe conditions, whereas the B-TRAN can both limit and terminate fault currents in microseconds.

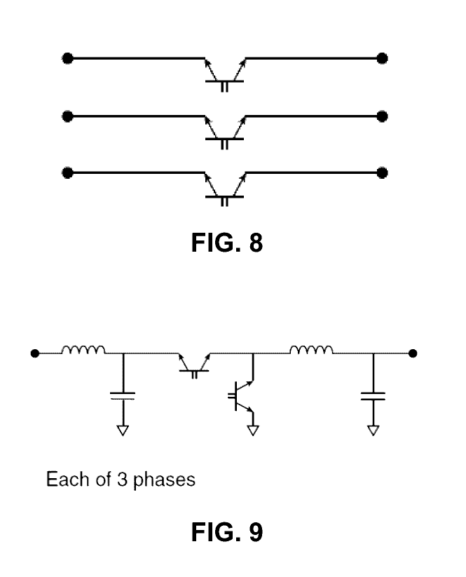

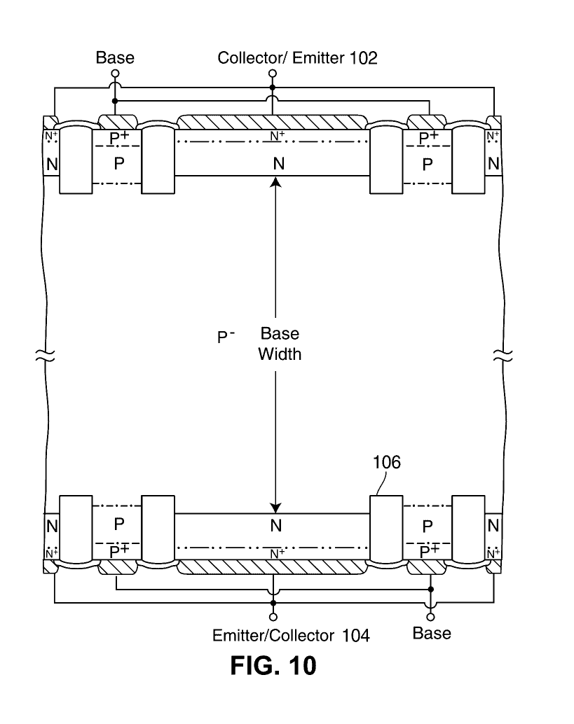

FIG. 8 shows the use of a bidirectional bipolar-conduction switch using multiple ON states can be connected as an AC switch for AC power control.

### AC Voltage Regulation

Most electric power worldwide is passed from distribution voltage to low voltage via transformers, but these transformers just step down the voltage without performing any regulatory function. Thus, the end user is subject to voltage variations which may damage equipment and cause excessive power consumption in both lighting and motors. The power converter of FIG. 9 is a simple buck converter, which is easily implemented with B-TRANs, but not so with conventional power switches, since the required switch operation is AC (bi-directional). This converter may be used wherever AC power voltage variations are excessive, or where precise AC voltage control is needed. Calculated switch losses for this low cost B-TRAN circuit are less than 0.3%.

### Matrix Converter Variable Frequency Drive (VFD)

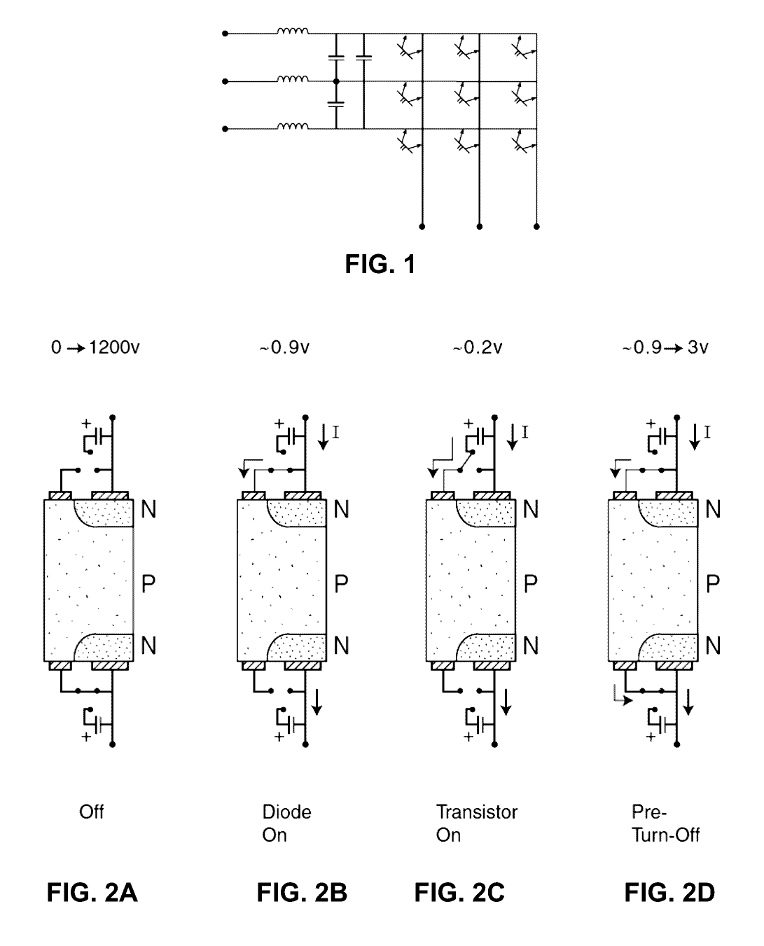

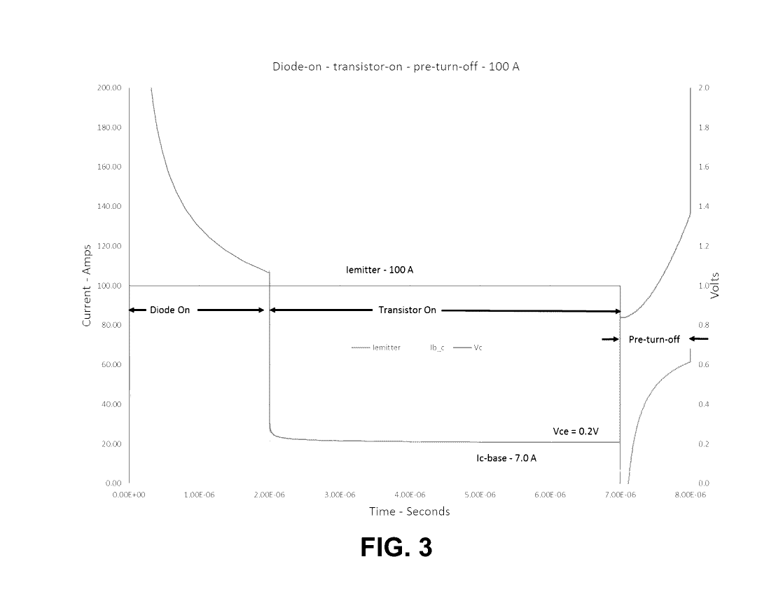

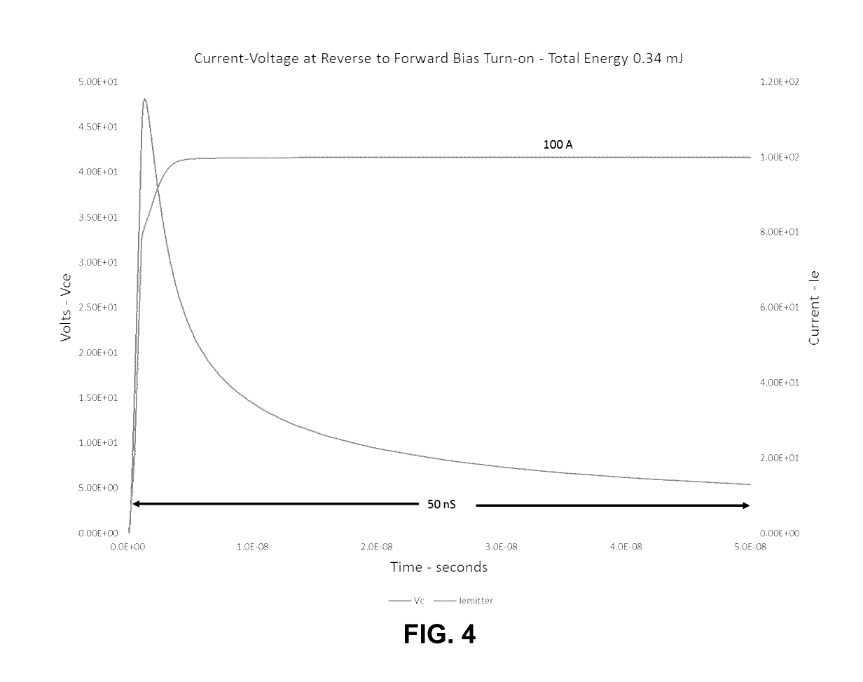

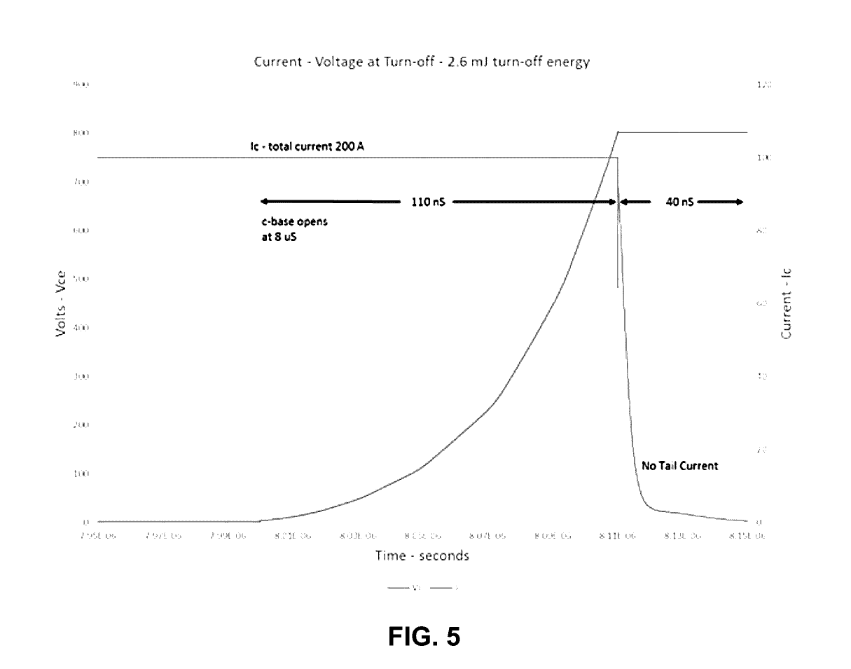

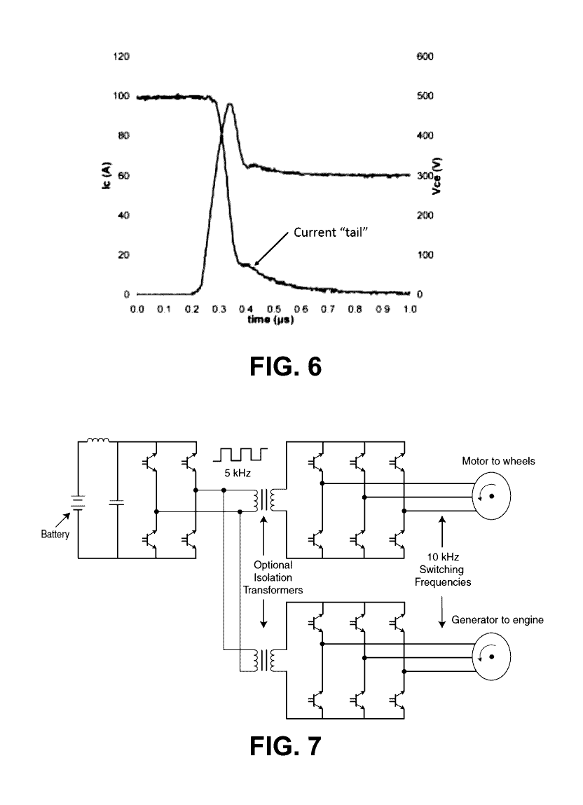

Electric Induction Motors consume about 40% of the world's electric power production. Most of these motors could have lower power consumption if the voltage and/or applied frequency were adjustable in order to optimize to load conditions. Existing VFDs are either large, expensive units with relatively low efficiency, or smaller, less expensive units with high line harmonics. The B-TRAN-based Matrix Converter of FIG. 1 can adjust both voltage and applied frequency to an induction motor, allowing it to operate at peak efficiency regardless of load conditions and incoming AC voltage. Again, this converter is easily implemented with B-TRANs, but not so with conventional power switches. This converter is expected to be small, compact, low cost, highly efficient, and operate with very low line harmonics. B-TRAN losses are expected to be less than 0.5%.

### Electric Vehicle (EV) Drives

The B-TRAN based EV Drive (FIG. 7) has an anticipated efficiency of over 99% between any two ports, resulting from the very low voltage drop and low turn-off losses of the B-TRAN, along with a converter topology that eliminates reverse recovery related losses. This high frequency square wave AC link topology (Ideal Power patent pending) also allows for compact, low loss transformer isolation between ports. Other ports may include an on-board generator (hybrid electric) and high power on-board charger. The projected high efficiency may allow low cost air cooling of the drive train on electric vehicles.

It should also noted that use of the multi-ON-mode switches in this architecture facilitates the adaptation of the vehicle for regeneration (e.g. using the motor to charge the battery when the vehicle is coasting downhill).

### Wind/Solar/Battery Converters Via PPSA

The AC switch characteristic of the B-TRAN is well suited for Ideal Power's Power Packet Switching Architecture (FIG. 11). Full power conversion efficiency with B-TRANs is anticipated to be better than 99%, resulting in compact, air cooled, low cost converters for renewable energy power generation in wind turbines, solar PV power, and hydroelectric power.

### Advantages

The disclosed innovations, in various embodiments, provide one or more of at least the following advantages. However, not all of these advantages result from every one of the innovations disclosed, and this list of advantages does not limit the various claimed inventions.
Improved efficiency in power conversion systems;
Power semiconductor devices with more ruggedness;
Power semiconductor devices with higher breakdown voltage;
Power semiconductor devices with lower on-resistance:
Power semiconductor devices with lower cost;
Integrable power semiconductor devices;
Motor operation with better control of power factor;
Better ground-fault protection in power conversion systems, with reduced likelihood of tripping ground-fault protection.

According to some but not necessarily all embodiments, there is provided: The present application teaches configurations in which the multiple-ON-mode bidirectional bipolar switch is used to provide very simple circuit configurations which can—when requirements are not stringent—perform certain electrical conversions which might otherwise require a PPSA (Power Packet Switching Architecture) converter.

According to some but not necessarily all embodiments, there is provided: An AC power converter, comprising: a plurality of per-phase buck converters, each comprising at least two symmetrically-bidirectional bipolar transistors, and control circuitry which operates each of the transistors with multiple ON states; and wherein each of the per-phase buck converters is connected between corresponding lines of first and second multiphase interfaces, and comprises at least one choke and at least one capacitor; and wherein each of the corresponding lines carries AC power.

According to some but not necessarily all embodiments, there is provided: A matrix converter, comprising: a first and a second power connection, each including multiple separate current-carrying non-neutral lines; and connecting switches which each link a respective one of the lines of the first power connection to a respective line of the second power connection, and which each comprise a symmetrically-bidirectional bipolar transistor, and control circuitry which operates each of the transistors with multiple different ON states in each switching cycle; wherein every non-neutral line in the first connection is connected, through one of the transistors, to a non-neutral line in the second connection.

### MODIFICATIONS AND VARIATIONS

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

What is claimed is, among others (and, without exclusion, in addition to any other points which are indicated herein as inventive and/or surprising and/or advantageous):

1. An AC power converter, comprising:
a plurality of per-phase buck converters, each comprising at least two symmetrically-bidirectional bipolar transistors, and control circuitry which operates each of the transistors with multiple ON states; and
wherein each of the per-phase buck converters is connected between corresponding lines of first and second multiphase interfaces, and comprises at least one choke and at least one capacitor;
and wherein each of the corresponding lines carries AC power.

2. The converter of claim 1, comprising three of the per-phase buck converters.

3. The converter of claim 1, wherein each of the transistors is a B-TRAN transistor.

4. The converter of claim 1, wherein each of the transistors is an M-TRAN switching device.

5. A matrix converter, comprising:
a first and a second power connection, each including multiple separate current-carrying non-neutral lines; and
connecting switches which each link a respective one of the lines of the first power connection to a respective line of the second power connection, and which each comprise a symmetrically-bidirectional bipolar transistor, and
control circuitry which operates each of the transistors with multiple different ON states in each switching cycle;
wherein every non-neutral line in the first connection is connected, through one of the transistors, to a non-neutral line in the second connection.

6. The converter of claim 5, wherein each of the connections comprises three non-neutral hot lines.

7. The converter of claim 5, wherein each of the transistors is a B-TRAN transistor.

8. The converter of claim 5, wherein each of the transistors is an M-TRAN switching device.
